(19) United States
(12) Patent Application Publication
(10) Pub. No.: US 2023/0341761 A1
(43) Pub. Date: Oct. 26, 2023

(54) ANTI-REFLECTION WITH INTERCONNECTED STRUCTURES

(71) Applicant: Edgehog Advanced Technologies Inc., Montreal (CA)

(72) Inventors: Chia-hung Calvin Cheng, Montreal (CA); Fabien Paul Jacques Dauzou, Montreal (CA); Siamak Kashi, Montreal (CA); Nasim Sahraei Khanghah, Montreal (CA)

(21) Appl. No.: 18/033,721

(22) PCT Filed: Oct. 26, 2021
(86) PCT No.: PCT/CA2021/051507

§ 371 Date: Apr. 25, 2023

Related U.S. Application Data
(60) Provisional application No. 63/105,673, filed on Oct. 26, 2020.

(51) Int. Cl. G03F 1/46; G03F 1/80; B82Y 20/00; B82B 3/00

(52) U.S. Cl. CPC G03F 1/46; G03F 1/80; B82Y 20/00; B82B 3/0014; B82B 3/0057; B82B 3/0066

(57) ABSTRACT

An anti-reflective article includes a substrate including a surface and a bulk, and an arrangement of anti-reflective nanostructures along the surface of the substrate, each anti-reflective nanostructure of the arrangement of anti-reflective nanostructures being supported by the bulk of the substrate, each anti-reflective nanostructure of the arrangement of anti-reflective nanostructure tapering from the bulk of the substrate to define a respective peak. At least some of the anti-reflective nanostructures of the arrangement of anti-reflective nanostructures are linked with an adjacent anti-reflective nanostructure of the arrangement of anti-reflective nanostructures via a respective interconnection. The respective interconnections are in addition to the bulk of the substrate supporting the anti-reflective nanostructures. The respective interconnections are disposed at or above a midpoint between the peaks of the anti-reflective nanostructures and the bulk of the substrate.

### CROSS-REFERENCE TO RELATED APPLICATION

This application claims the benefit of U.S. provisional application entitled “Anti-Reflection with Interconnected Structures,” filed Oct. 26, 2020, and assigned Ser. No. 63/105,673, the entire disclosure of which is hereby expressly incorporated by reference.

### BACKGROUND OF THE DISCLOSURE

### Field of the Disclosure

The disclosure relates generally to anti-reflection surfaces.

### Brief Description of Related Technology

Anti-reflection surfaces have been used in a variety of contexts, including solar modules, solar collectors, optical components, and displays. Applied on the cover of solar panels, anti-reflective technology can lead to increased transmission of light into the module. Solar collectors benefit from decreased reflection or increased transmission of light to enhance the capture or conversion of solar energy into thermal energy. In optical components, reflection and scattering can contribute to noise, such as lens flare, thereby degrading signal quality. For electronic displays, the reflection of light off the surface of cover can interfere with the light specifically emitted or reflected by the display.

Specular reflection of incoming light or other electromagnetic radiation occurs at an interface where there is a sudden change in the index of refraction from the original medium to the second medium. This change results in refraction and transmission, in addition to reflection. The amount of reflection increases as the difference between the indices of the two materials increases. Also, as the incidence angle increases from normal or perpendicular to the surface, reflection increases.

Various attempts have been made to reduce reflection. Traditional thin-film dielectric coatings add layers of material on the surface, but generally cannot substantially compensate for the large reflection at wide angles from normal. Other approaches include surface texturing and the use of nanoparticles. However, when feature sizes of the surface textures and particles are near or larger than the wavelength of the incoming electromagnetic radiation, high scattering may nonetheless occur without increasing transmission.

Conventional anti-reflection technology uses thin film coatings of dielectric materials, such as solid or porous MgF₂, SiO₂, ZnSe, SnO₂, and ZnS. When deposited with thickness at half or quarter of the target wavelength, such layers can specifically reduce reflection around that wavelength. However, anti-reflection effects for other non-specific wavelengths are limited. Furthermore, such anti-reflection effects are typically tuned for normal incidence, where the light hits the surface perpendicular to the surface. Such anti-reflection coatings lack the ability to neutralize increasing Fresnel reflection as incidence angle deviates from normal. Furthermore, because such layers can have different thermal expansion coefficients than the substrate, thermal cycling can lead to peeling, delamination or other damage.

Microstructured surfaces have also been used to scatter incoming light. Microstructured structures are effective at various angles. However, the scattering of light contributes to high haze and can accumulate dirt inside the structures, without necessarily increasing transmission.

Subwavelength nanostructured surfaces have exhibited adjustments to haze depending on the physical dimensions. However, in order to have an anti-reflective optical effect, such structures typically have sizable depth to lateral ratio, making such structures mechanically fragile. The structures are also exposed to wear and tear in the environment. Still further, the structural integrity of the structures is challenged during assembly, transportation, and application in the field. The small, sub-wavelength features of such nanostructured surfaces can thus be damaged mechanically in multiple ways. Nanopillars and similar structures with a large depth to lateral ratio are especially susceptible to such damage. While larger structures have higher mechanical resistance, such larger structures scatter light without increasing transmission, and debris can accumulate on the surfaces thereof.

### SUMMARY OF THE DISCLOSURE

In accordance with one aspect of the disclosure, an anti-reflective article includes a substrate including a surface and a bulk, and an arrangement of anti-reflective nanostructures along the surface of the substrate. Each anti-reflective nanostructure of the arrangement of anti-reflective nanostructures is supported by the bulk of the substrate. Each anti-reflective nanostructure of the arrangement of anti-reflective nanostructure tapers from the bulk of the substrate to define a respective peak. At least some of the anti-reflective nanostructures of the arrangement of anti-reflective nanostructures are linked with an adjacent anti-reflective nanostructure of the arrangement of anti-reflective nanostructures via a respective interconnection, the respective interconnections being in addition to the bulk of the substrate supporting the anti-reflective nanostructures. The respective interconnections are disposed at or above a midpoint between the peaks of the anti-reflective nanostructures and the bulk of the substrate.

In accordance with another aspect of the disclosure, an anti-reflective article includes a substrate having a surface and a bulk, and an arrangement of anti-reflective nanostructures along the surface of the substrate. Each anti-reflective nanostructure of the arrangement of anti-reflective nanostructure is supported by the bulk of the substrate. Each anti-reflective nanostructure of the arrangement of anti-reflective nanostructure tapers from the bulk of the substrate to define a respective peak. A height at which adjacent anti-reflective nanostructures of the arrangement of anti-reflective nanostructures are linked by an interconnection varies across the substrate. At least some of the interconnections are disposed at a position equidistant between the peaks of the anti-reflective nanostructures and the bulk of the substrate.

In accordance with yet another aspect of the disclosure, an anti-reflective article includes a substrate including a surface and a bulk, and an arrangement of anti-reflective nanostructures along the surface of the substrate. Each anti-reflective nanostructure of the arrangement of anti-reflective nanostructures is supported by the bulk of the substrate. Each anti-reflective nanostructure of the arrangement of anti-reflective nanostructure tapers from the bulk of the substrate to define a respective peak. Some of the anti-reflective nanostructures of the arrangement of anti-reflective nanostructures are linked with an adjacent anti-reflective nanostructure of the arrangement of anti-reflective nanostructures via a portion of the substrate in addition to the bulk of the substrate. The portion defines a saddle-shaped section of the surface.

In accordance with still another aspect of the disclosure, an anti-reflective article includes a substrate having a surface and a bulk, the surface being shaped to define an arrangement of anti-reflective nanostructures, each anti-reflective nanostructure of the arrangement of anti-reflective nanostructure tapering from the bulk of the substrate to define a respective peak, and a distribution of material across the surface of the substrate. A portion of the distribution of material is disposed between adjacent anti-reflective nanostructures of the arrangement of anti-reflective nanostructures such that the adjacent anti-reflective nanostructures of the arrangement of anti-reflective nanostructures are interconnected by the portion of the distribution of material.

In accordance with yet another aspect of the disclosure, a method of fabricating an anti-reflective article includes forming a mask on a substrate, the mask having a lamellar nanopattern, and etching the substrate through openings in the mask defined by the lamellar nanopattern. Etching the substrate includes implementing an anisotropic etch such that an arrangement of tapered nanostructures are formed in accordance with the lamellar pattern.

In accordance with yet another aspect of the disclosure, a method of fabricating an anti-reflective article includes forming a mask on a substrate, the mask having a nanopattern of holes, and etching the substrate through the holes in the mask defined by the nanopattern. Etching the substrate includes implementing an anisotropic etch such that an arrangement of tapered nanostructures is formed in accordance with the nanopattern of holes. The nanopattern of holes is configured such that the arrangement of tapered nanostructures has saddle-shaped surfaces at interconnections between adjacent tapered nanostructures of the arrangement of tapered nanostructures.

In connection with any one of the aforementioned aspects, the articles and/or methods described herein may alternatively or additionally include or involve any combination of one or more of the following aspects or features. The substrate includes the respective interconnections. The interconnections are provided by a portion of the substrate between the adjacent anti-reflective nanostructures of the arrangement of anti-reflective nanostructures. The portion of the substrate defines a saddle-shaped section of the surface. The anti-reflective article further includes a distribution of nanoparticles disposed across the surface of the substrate such that each interconnection is provided by a respective subset of the distribution of nanoparticles. The nanoparticles in each subset closest to the peak are larger than the nanoparticles in each subset closest to the bulk. The anti-reflective article further includes a distribution of flakes across the substrate. Each flake of the distribution of flakes is in contact with the peaks of linked anti-reflective nanostructures of the arrangement of anti-reflective nanostructures such that each flake of the distribution of flakes provides one or more of the interconnections. The anti-reflective article further includes a filling across the substrate disposed in cavities defined by the arrangement of anti-reflective nanostructures such that each interconnection is provided by a respective portion of the filling. The anti-reflective article further includes a continuous film extending across the arrangement of anti-reflective nanostructures such that the continuous film provides the interconnections between the peaks of the anti-reflective nanostructures. The arrangement anti-reflective nanostructures is configured such that the peaks of each pair of adjacent anti-reflective nanostructures in the arrangement of anti-reflective nanostructures are spaced apart by a distance smaller than a wavelength of light incident upon the anti-reflective article. The arrangement of anti-reflective nanostructures establishes an effective index of refraction for light incident upon the anti-reflective article. Each anti-reflective nanostructure of the arrangement of anti-reflective nanostructures is configured such that the effective index of refraction exhibits a continuous gradient from the respective peak of the anti-reflective nanostructure to a base of the anti-reflective nanostructure. The substrate includes a base substrate and a layer supported by the base substrate. The layer includes the arrangement of anti-reflective nanostructures. The surface of the substrate is shaped to define the arrangement of anti-reflective nanostructures. Each pair of adjacent anti-reflective nanostructures of the arrangement of anti-reflective nanostructures is interconnected by a respective portion of the substrate. The adjacent anti-reflective nanostructures of the arrangement of anti-reflective nanostructures define a saddle-shaped surface. The anti-reflection article further includes a plurality of nanoparticles distributed across the arrangement of anti-reflective nanostructures such that each pair of adjacent anti-reflective nanostructures of the arrangement of anti-reflective nanostructures is interconnected by a respective subset of the plurality of nanoparticles. The number of the nanoparticles in each subset varies such that the depth at which adjacent anti-reflective nanostructures of the arrangement of anti-reflective nanostructures are interconnected varies. Positioning of the nanoparticles in each subset varies such that the depth at which adjacent anti-reflective nanostructures of the arrangement of anti-reflective nanostructures are interconnected varies. Each subset includes nanoparticles of varying size. The distribution of material includes a plurality of nanoparticles disposed in cavities defined by the arrangement of anti-reflective nanostructures. The distribution of material includes a distribution of flakes across the substrate such that each flake of the distribution of flakes interconnects two or more of the peaks of the anti-reflective nanostructures. The material of the distribution includes a filling across the substrate disposed in cavities defined by the arrangement of anti-reflective nanostructures. The material of the distribution includes a continuous film extending across the arrangement of anti-reflective nanostructures such that the continuous film provides the interconnections between the peaks of the anti-reflective nanostructures.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a schematic, side view of an anti-reflection article with an arrangement of interconnected nanostructures in accordance with one example.

FIG. 2 depicts the anti-reflection article of claim 1 in connection with light at another angle of incidence.

FIG. 3 is a graphical plot of light transmittance of an anti-reflection article for various angles of incidence, the anti-reflection article having arrangements of interconnected nanostructures on both sides of a substrate in accordance with one example.

FIG. 4 depicts plan and sectional, scanning electron microscopy (SEM) images of an arrangement of interconnected nanostructures in accordance with one example.

FIG. 5 depicts plan, SEM images of arrangements of interconnected nanostructures resulting from etch procedures with varying levels of selectivity between an etch mask and a substrate in accordance with one example.

FIG. 6 depicts top and cross-sectional views of an anti-reflection article having an arrangement of nanostructures interconnected at varying depths in accordance with one example.

FIG. 7 depicts sectional and plan, SEM images of an arrangement of interconnected nanostructures in accordance with one example.

FIG. 8 depicts a schematic, side view of an anti-reflection article having an arrangement of nanostructures interconnected at varying depths, along with a schematic, plan view of a hole-based mask used to fabricate the nanostructures, in accordance with one example.

FIG. 9 depicts sectional and plan, SEM images of an anti-reflection article having an arrangement of nanostructures interconnected at varying depths in accordance with one example.

FIG. 10 depicts sectional SEM images of examples of anti-reflection articles with arrangements of nanostructures interconnected at varying depths.

FIG. 11 depicts oblique sectional SEM images of an anti-reflection article having an arrangement of nanostructures interconnected at varying depths in accordance with another example.

FIG. 12 depicts plan SEM images of examples of anti-reflection articles having arrangements of nanostructures with shallow etch depths.

FIG. 13 depicts a sectional, schematic view of an anti-reflection article with an arrangement of nanostructures interconnected by pluralities of nanoparticles in accordance with one example.

FIG. 14 depicts a sectional SEM image of an anti-reflection article with a nanoparticle-interconnected arrangement of nanostructures in accordance with one example.

FIG. 15 depicts a sectional, schematic view of an anti-reflection article with an arrangement of nanostructures interconnected by a filling in each cavity or gap in the arrangement in accordance with one example.

FIG. 16 depicts a sectional, schematic view of an anti-reflection article with an arrangement of nanostructures interconnected by a continuous blanket or film in accordance with one example.

FIG. 17 depicts SEM images of an anti-reflection article with an arrangement of nanostructures interconnected by a continuous blanket in accordance with one example.

FIG. 18 depicts a sectional, schematic view of an anti-reflection article with an arrangement of nanostructures interconnected by a distribution of flakes in accordance with one example.

FIG. 19 depicts a plan, schematic view of an anti-reflection article with an arrangement of nanostructures interconnected by a distribution of flakes in accordance with one example.

FIG. 20 is a side view on a superhydrophobic glass substrate with interconnected nanostructures and deposited hydrophobic fluorocarbon molecules to depict the water contact angle on its surface in accordance with one example.

The embodiments of the disclosed articles, systems, and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Anti-reflective articles with interconnected nanostructures are described. Methods for fabricating such articles are also described. The interconnections between adjacent nanostructures provide mechanical stability without detrimentally affecting optical performance. A robust sub-wavelength arrangement of nanostructures is therefore provided. The interconnections are also configured such that a gradual change in refractive index provided by the nanostructures is still provided. The interconnections also maintain a self-cleaning feature of the anti-reflective articles. These performance and other characteristics of the anti-reflective articles are maintained despite disposition of interconnections at or above a midpoint of the nanostructures. As described and shown herein, respective interconnections are disposed at or above the midpoint between a peak of the nanostructures and a bulk of a substrate from which the nanostructures extend. The interconnected nanostructured surface is provided in a manner compatible with surfaces configured for superhydrophilic or superhydrophobic properties, and/or other surface features such as oleophobicity.

The disclosed articles and methods may provide various types of interconnections. In some cases, the interconnections are an integral portion of the substrate in which the nanostructures are formed. In such cases, the depth to which the substrate is etched to form the nanostructures varies. The surface of the substrate may thus be saddle-shaped, as shown and described herein. Alternatively or additionally, the interconnections are provided by nanoparticles distributed across the substrate. In some cases, the size of the nanoparticles progressively increases as the distance from the substrate bulk increases. The cavities between adjacent nanostructures may thus be filled more effectively. The interconnections may alternatively or additionally be provided by a distribution of flakes in contact with the peaks of the nanostructures. Still other options include a filling disposed in the cavities and/or a continuous blanket or other film across the peaks. In each of these cases, the interconnections may be composed of, or otherwise include, a material such that the anti-reflective properties and performance of the disclosed articles are maintained.

The disclosed anti-reflective articles include an arrangement of nanostructures that provides a gradient in the index of refraction. The refractive index gradient may be configured as presented by moth-eye and/or other nanostructure arrangements. The disclosed anti-reflective articles are thus capable of providing a broad-spectrum, omni-directional anti-reflection surface that can be self-cleaning while maintaining mechanical and thermal durability.

The disclosed anti-reflective articles may be applied as a cover for solar panels. The anti-reflection performance results in greater transmission of light, allowing for higher energy production. The self-cleaning aspect of the disclosed anti-reflective articles reduces the need for frequent cleaning and ensures maximized energy production at all times. The mechanical and thermal stability of the disclosed anti-reflective articles is useful in several respects, including, for instance, during manufacturing, assembly, transportation, installation, and use. The durability is therefore consistent with solar panels otherwise having a long operational lifetime.

The disclosed anti-reflective articles are not limited to use with solar panels, but are instead useful in a wide variety of applications. For instance, the disclosed anti-reflective articles may be used in connection with devices and systems, such as optical components, lenses, laser components, windows, picture frames, display boxes, LED and OLED lighting, and electronic displays. In electronic displays, the durable reduction of reflection provided by the disclosed articles does not introduce haze. An increase in contrast ratio for both emissive and reflective displays may thus be provided.

As described below, the anti-reflective surface of the disclosed anti-reflective articles may include sub-wavelength nanostructures along a surface with transmissive or absorbing properties over a range of electromagnetic wavelengths. The structures have peaks to establish a gradual change in refractive index, as opposed to, for instance, flat tops that may create a discrete, step change in index. The structures are interconnected at or below the peaks to enhance high mechanical resistance. The structures may exhibit self-cleaning properties. A self-cleaning surface is also desirable when the substrate is used as a cover material.

The interconnections and other elements of the disclosed anti-reflective articles may function over a broad spectrum and for various angles of incidence. In some cases, the disclosed anti-reflective articles provide a highly transmissive surface with controlled variable haze. Adjustable haze is important to control the level of clarity of a transmissive substrate.

The interconnected nanostructures may feature lateral dimensions smaller than the wavelength of light. For example, the peak-to-peak lateral spacing of the nanostructures may be smaller than 100 nanometers (nm). The vertical dimensions of the nanostructures may be comparable or greater than the wavelength of light. For example, the nanostructures may have a height larger than 100 nm.

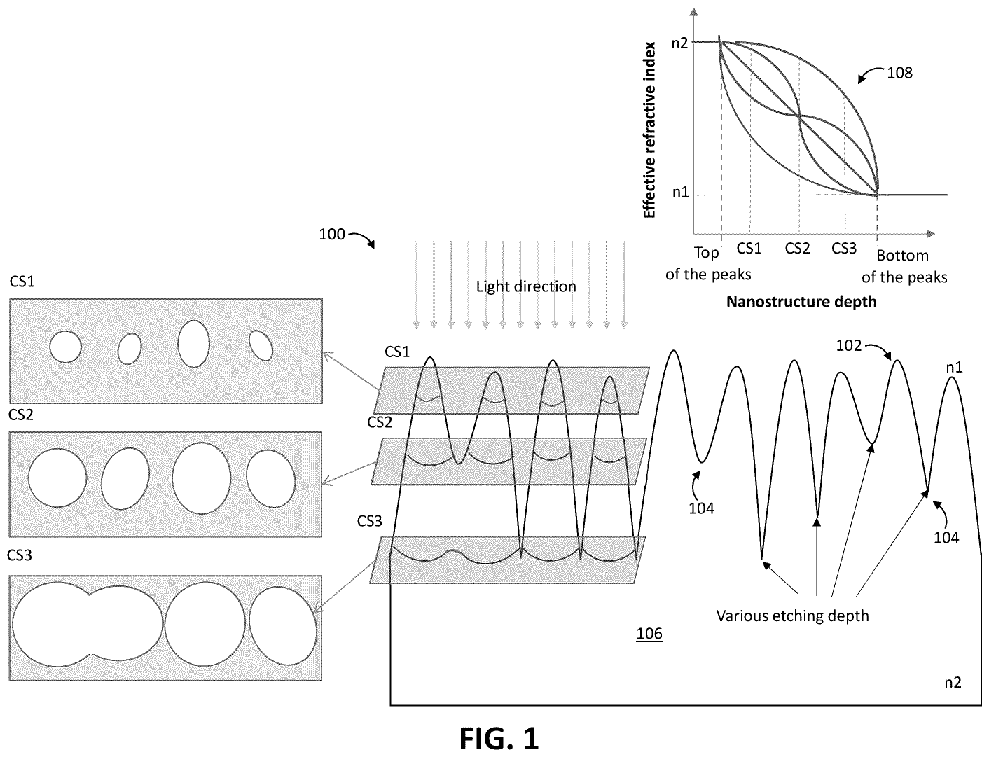

The nanostructures feature subwavelength lateral dimensions, where an effective index of refraction may be averaged for the cross-sectional area of the surface and that changes through the depths (or vertical dimension) of the nanostructures. Further details are shown in connection with the example of FIG. 1.

The nanostructures establish an interface between two media that features a continuous gradient in the effective index of refraction from the first medium through the surface nanotextures into the second medium, creating a broad-spectrum anti-reflection effect.

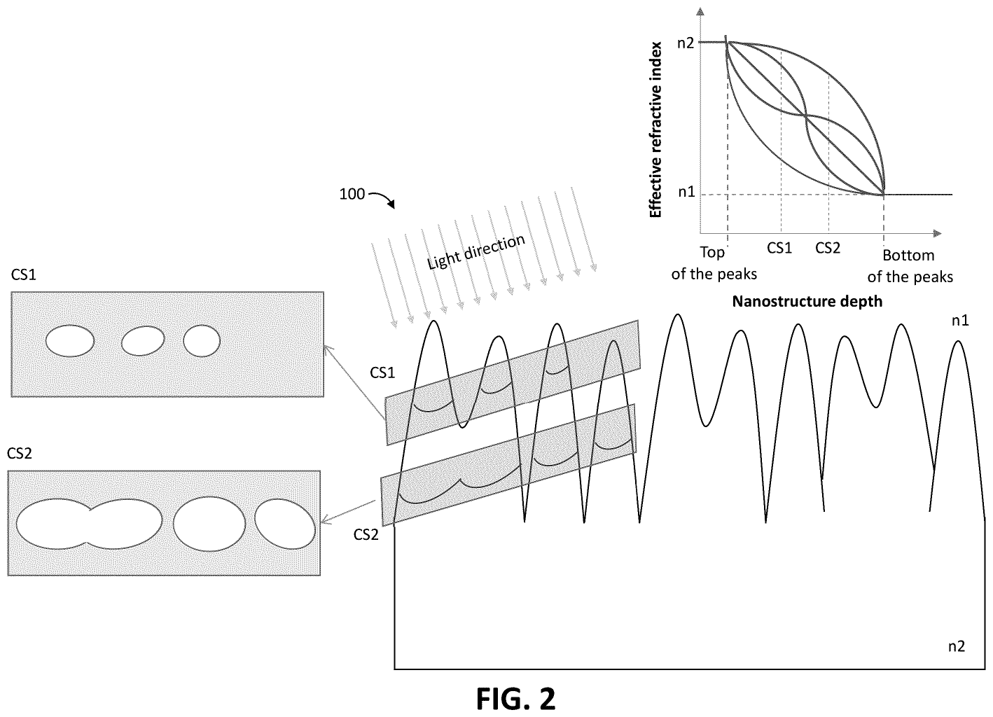

The nanostructures have sufficient depth relevant to the wavelength of light at any incidence angle, creating a continuous gradient in the index of refraction for incident light of all angles and granting an omni-directional anti-reflection effect that features high transmission at all angles. Further details are shown in connection with the example of FIG. 2.

The nanostructures feature subwavelength lateral dimensions and may control the haze such as minimizing haze at smaller dimensions.

The nanostructures are interconnected so as to grant mechanical stability while maintaining the continuous gradient in the effective index of refraction from the top of the structures to the bottom. The nanostructures may be connected in the middle, top, or combinations of the two at various depths.

The nanostructures may include a surface deposition of molecules or elements of high or low surface energy to grant the surface superhydrophilic or superhydrophobic properties, respectively, and other surface features such as oleophobicity.

Another aspect of the invention teaches a method of fabricating thermally and mechanically stable interconnected subwavelength nanostructures on at least one surface of a substrate such as glass, polymer, semi-conductor, ceramics and other materials, creating broad-spectrum and omni-directionally anti-reflective surfaces that may feature surface properties such as superhydrophobicity, superhrophilicity, oleophobicity, and others.

Reactive ion etching or any other dry or wet etching method may be used to create nanostructures into the substrate such that the nanostructures are interconnected and also give anti-reflection properties.

Hard masks of various designs may be used to etch nanostructures that are interconnected at the top, middle or a combination of the different portions of the nanostructures. The top view of the hard mask includes separate islands or a continuous network of interconnected shapes. In some cases, the two-dimensional shapes may include one or a combination of regular geometries such as circular shapes and/or parabolic shapes, and/or various irregular shapes.

The hard masks may vary in composition, density, and thickness in various areas of the surface. Varying the composition of the hard mask features may vary selectivity or durability against the substrate when exposed to primarily etching. Varying the density or thickness of the mask may lead to a variety of etch rates. With variance in the degradation of the mask at different lateral areas, the surface of the substrate is exposed at different times, thus allowing for etching of the surface to create various interconnected nanostructures with varying etch depths and geometries. Furthermore, a combination of isotropic and anisotropic etching of the substrate material may be used to establish longer durations of lateral etching at the top of the nanostructures, creating a tapered etching geometry.

The disclosed methods may include modifying the surface of the nanostructures. For instance, the composition of the nanostructures may be modified.

Nanoparticles and porous materials and polymers may be deposited between the nanostructures to connect them and give an anti-reflective property and enhance mechanical durability. Deposition methodology may include solution based deposition, vapor deposition, or vacuum-based deposition such as chemical vapor deposition, or plasma enhanced deposition, or atomic layer deposition.

The top of nanostructures may be connected via deposition of materials that cover and connect a plurality of nanostructures. Deposition methodology may include solution-based deposition of planar particles, vacuum-based deposition such as chemical vapor deposition and sputtering, and contract printing.

FIG. 1 shows an article 100 with interconnected nanostructures 102 with various height, depth, and interconnections 104 at various depths in accordance with one example. The article 100 establishes an interface that includes media, with a substrate 106 having index of refraction of n2 and an external medium has index of n1. Cross-sections CS1, CS2, and CS3 show the cross section (CS) of the nanostructures 102 at various depths when light hits the surface at normal incidence (perpendicular to the surface). The white circles are representative of the substrate material with refractive index of n2 and shaded regions represent the external medium with index of n1. Because of the subwavelength nature of the nanostructures 102, the wavefront sees the cross sectional area average of the refractive index. As a result, the effective refractive index changes continuously from n1 to n2 as the light travels from the top to the bottom of the nanostructures 102. FIG. 1 also includes a graphical plot 108 that shows various possible continuous gradient in the refractive index. The vertical lines in the refractive index figure represent different profile or depth of changing refractive index, which depends on the shape and heights of the nanostructures 102.

FIG. 2 shows a pair of cross sections CS1, CS2 of the article 100 when the light hits the surface of the article 100 at an oblique angle (non-perpendicular to the surface). A continuous gradient in the cross-sectional area and effective index of refraction may be observed for distances along the path of the light. The cross sections CS1, CS2 refer to planes perpendicular to the path of the light.

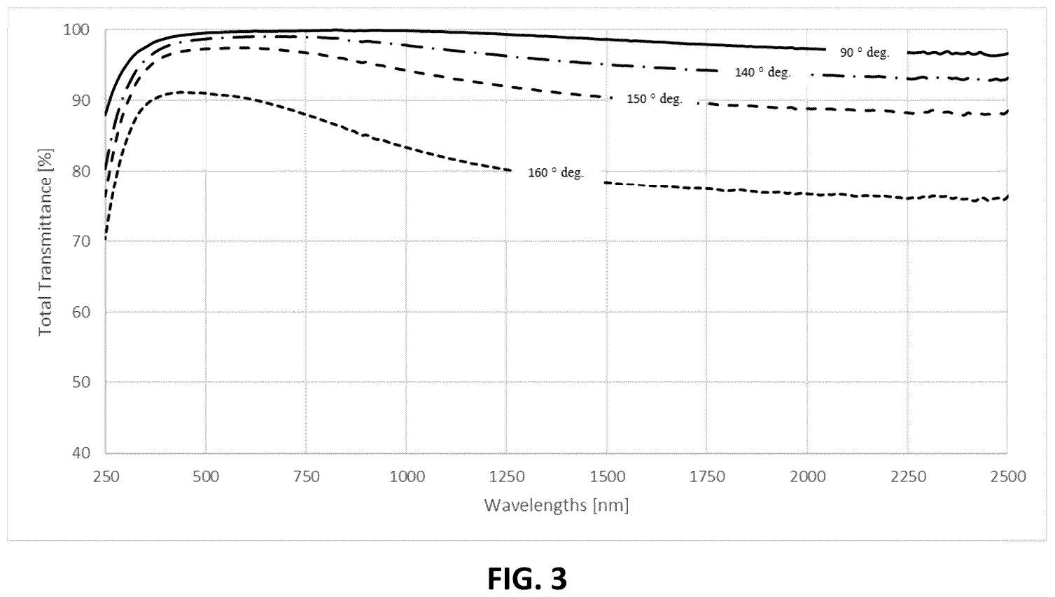

FIG. 3 shows a graphical plot of the total transmittance of light for a glass substrate treated with nanotexturing on both surfaces of the substrate. Transmittance is graphed as a function of wavelength at various angles of incidence. Normal incidence is represented by 90 degrees, and the other incident angles are also measured as the angle of the beam relative to the surface of the substrate. In other words, 70 degrees from normal is represented by 160 degrees in this figure (90+70=160 degrees).

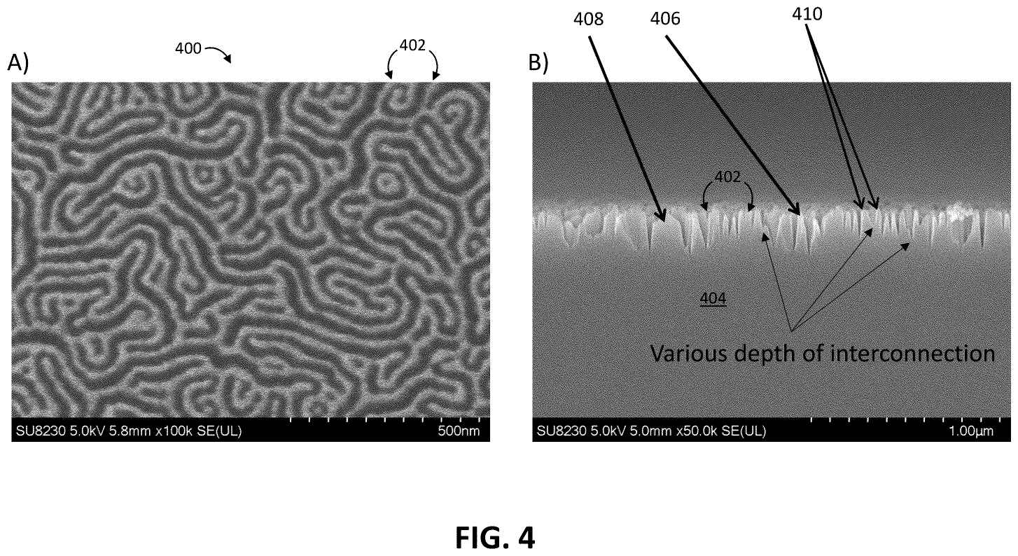

Part A of FIG. 4 shows a top view SEM image of an article 400 in accordance with one example. The article 400 includes interconnected nanostructures 402 in a substrate 404 created by etching the material (in this case, glass) via the use of a hard-mask with similar pattern as the white or lighter regions. Further details regarding an examples of masks, and methods of creating such masks are provided hereinbelow. Part B of FIG. 4 shows a cross section of the article 400 to depict the manner in which the nanostructures 402 are interconnected at various depths. In this example, the cross sectional area of the nanostructures 402 may resemble or include peaks 406, walls 408, or double peaks 410.

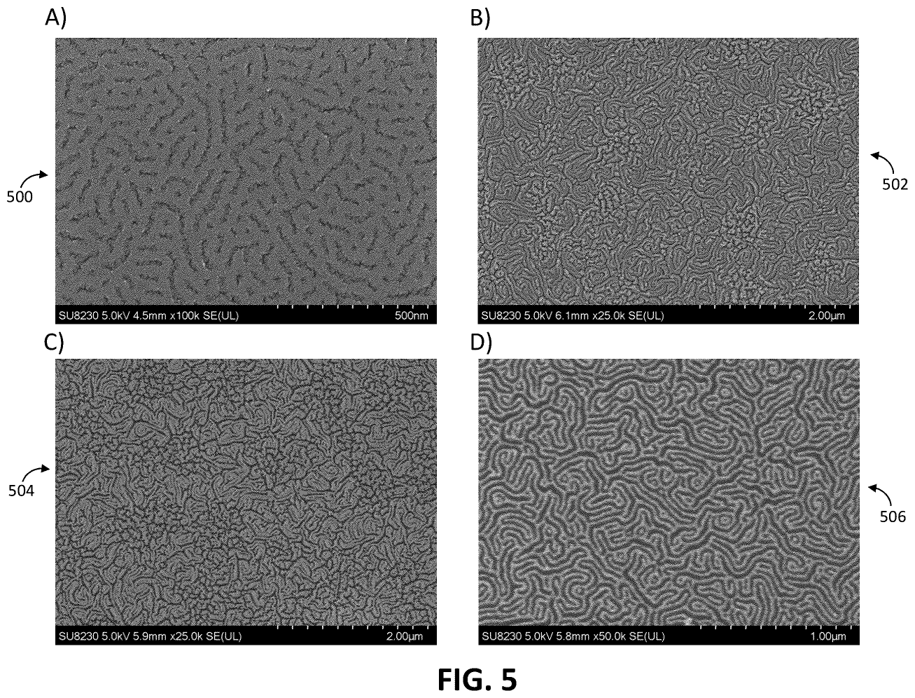

FIG. 5 depicts SEM images of top views of example articles 500 (Part A), 502 (Part B), 504 (Part C), and 506 (Part D), each having interconnected nanostructures created by etching the substrate through a hard mask of differing mask geometry using etchant with varying selectivity between the mask and substrate.

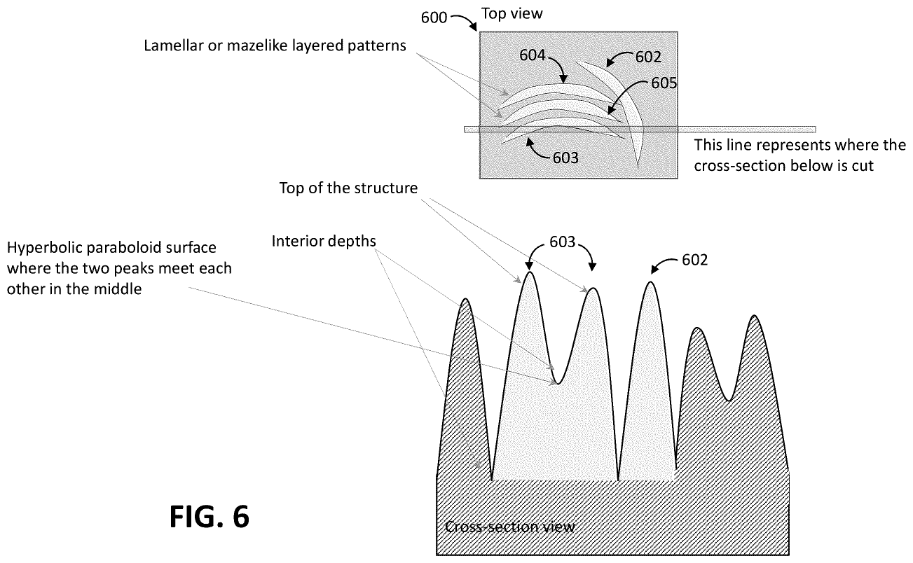

FIG. 6 shows top and cross-sectional views of an article 600 having interconnected nanostructures 602-605 where the nanostructures 602 are interconnected at the interior depth of the nanostructures 602 at various depths. In this example, the nanostructures 602-605 also have varying heights. For simplicity, only the shaded nanostructures 602, 603 are shown in the top view. As shown in the top view, the nanostructures 602-605 have lamellar or mazelike layered patterns. One or more of the interconnections defines a hyperbolic paraboloid surface where the peaks of the nanostructures 602 meet each other in the middle.

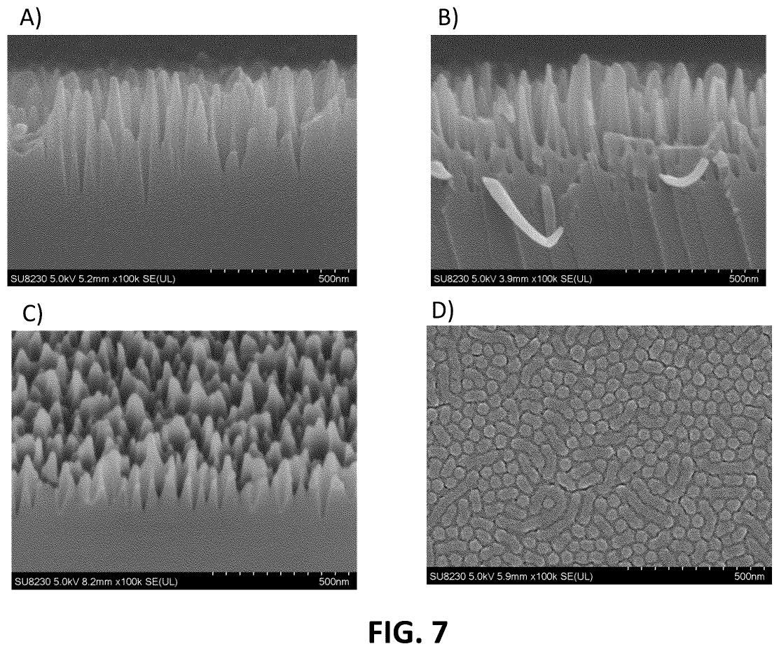

FIG. 7 shows interconnected nanostructures in the surface of a glass substrate created by a hard mask with geometry resembling an array of islands. The nanostructures feature various heights and depths, with nanostructures connected at various depths. In this example, Part A of FIG. 7 shows a cross section perpendicular to the surface. Part B of FIG. 7 shows a cross section at an angle not perpendicular to the surface, revealing holes and interconnected substrate material in the diagonal cross section. Part C of FIG. 7 shows a view at 30 degrees relative to the surface. Part D of FIG. 7 shows a top view of the nanostructured substrate surface that also resembles the geometries of the hard mask.

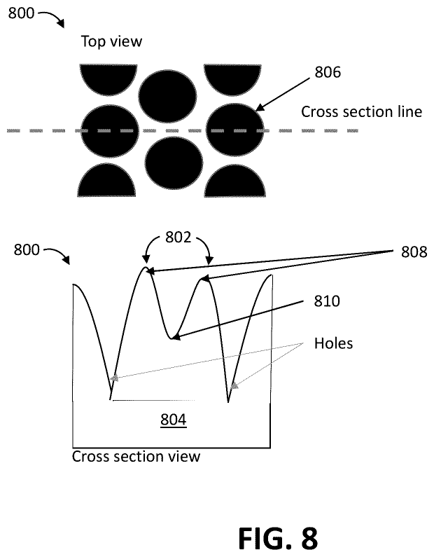

FIG. 8 shows a cross-sectional view of an article 800 having interconnected nanostructures 802 in a substrate 804 with a network matrix. The article 800 exhibits a hole-like geometry when viewed from the top. FIG. 8 also depicts a schematic, top view of the article 800 during fabrication. In the top view, darkened regions 806 represent valleys in the nanostructures 802 and roughly correspond to areas of the substrate 804 not protected by the mask prior to etching. The cross sectional view along the dashed line features a double peak 808 connected in the middle with a hyperbolic paraboloid (saddle like) surface 810. In the top view, the light area is where the mask has covered the surface during the etching and the dark area is where holes are formed during the etching. The hyperbolic surface is formed because of the difference in the lateral dimension of the mask in the middle. Moving along the dashed line in the top view, the lateral dimension of the mask perpendicular to the dashed line varies.

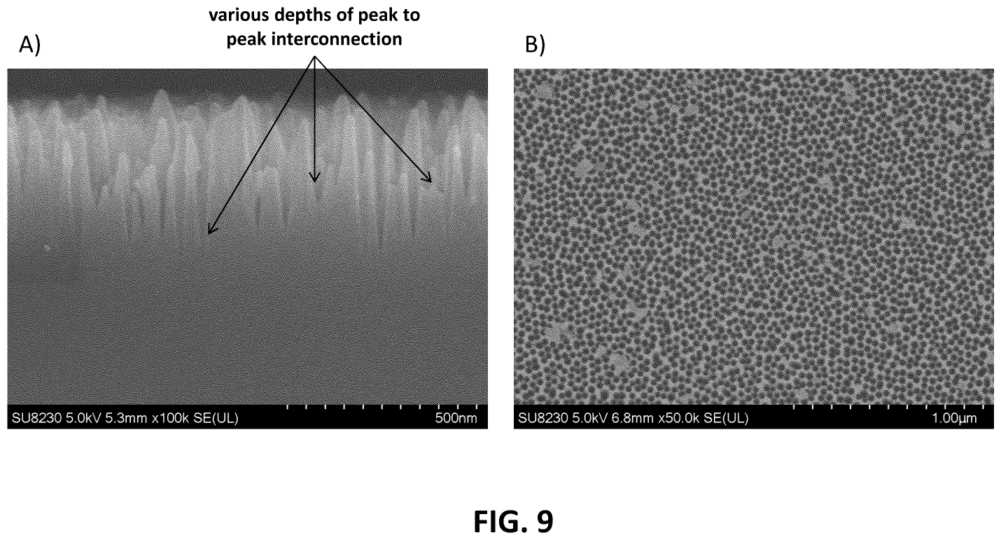

Part A of FIG. 9 shows a SEM image of the top view of interconnected structures in the surface of a substrate. Part B of FIG. 9 shows the top view of the same nanostructured surface where dark regions show deeper valleys in the nanostructures. The network-like light regions also resemble the geometry of the mask used to etch such nanostructures. Part B of FIG. 9 shows the SEM cross section of the same structure. Peaks are interconnected and do not resemble grass-like or needle-like structures.

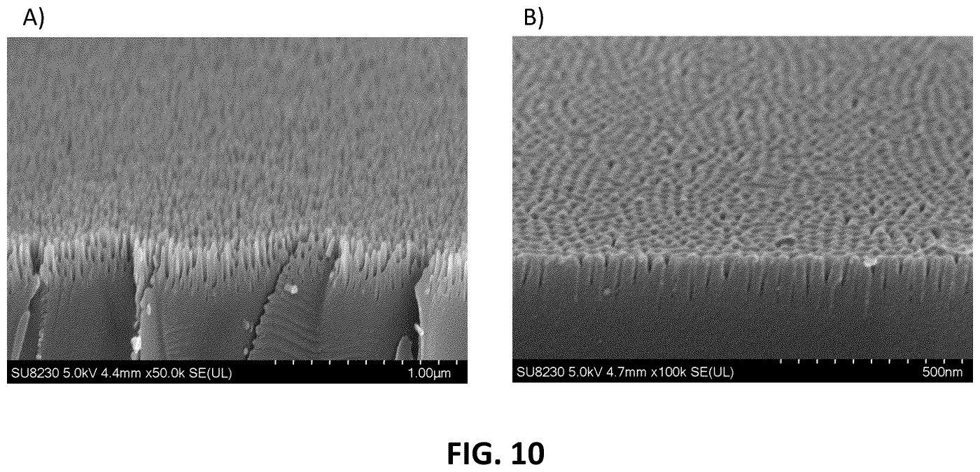

Part A of FIG. 10 shows a SEM image of the oblique view of interconnected nanostructures in a substrate surface with peaks interconnected at various depths. The oblique or diagonal cross section reveals holes within an interconnected matrix of substrate material, revealing the interconnected nature of the nanostructures. Part B of FIG. 10 shows an interconnected nanostructure surface with more shallow etch depths.

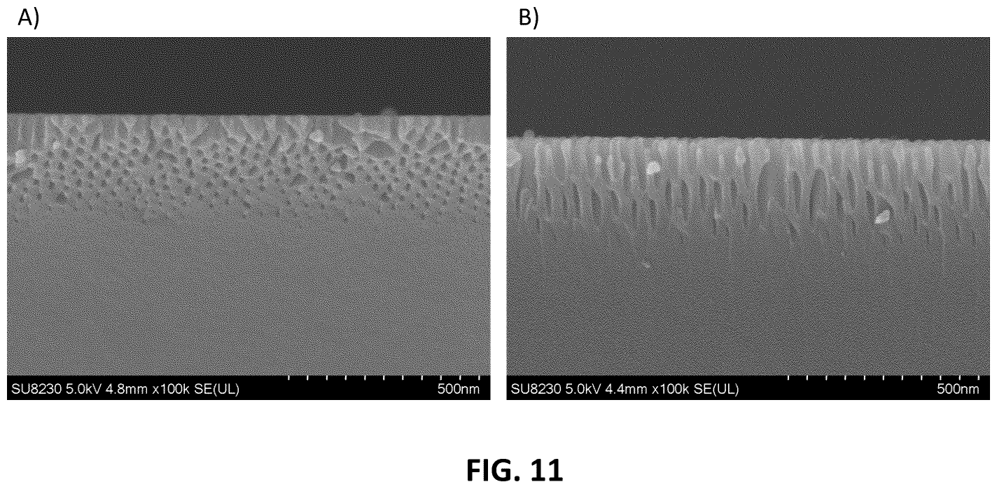

Parts A and B of FIG. 11 show cross-sectional SEM images of the oblique cut of a substrate with interconnected nanostructures in its surface. The diagonal or oblique cross section reveals a series of holes within a matrix of interconnected substrate material, revealing the interconnected nature of the nanostructures.

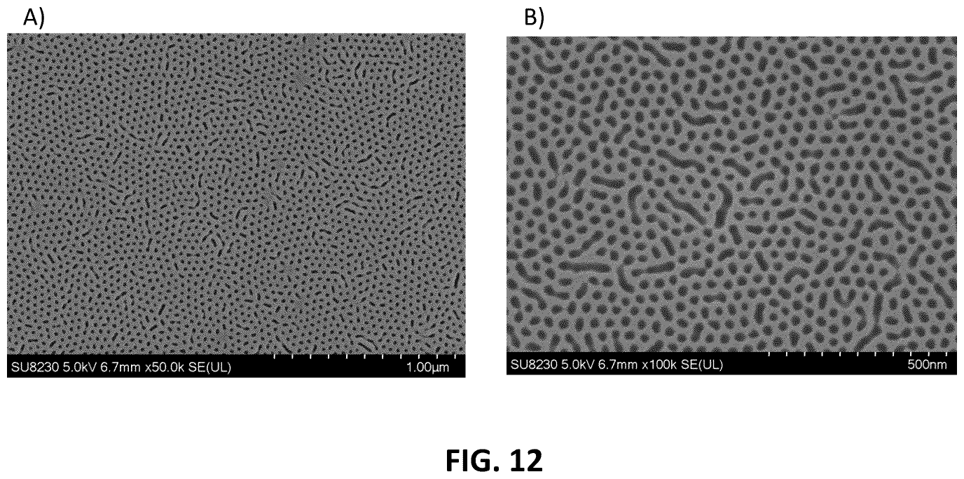

Parts A and B of FIG. 12 show the top views of a nanostructured surfaces similar to the examples of FIGS. 9 to 12 but with shallow etch depths.

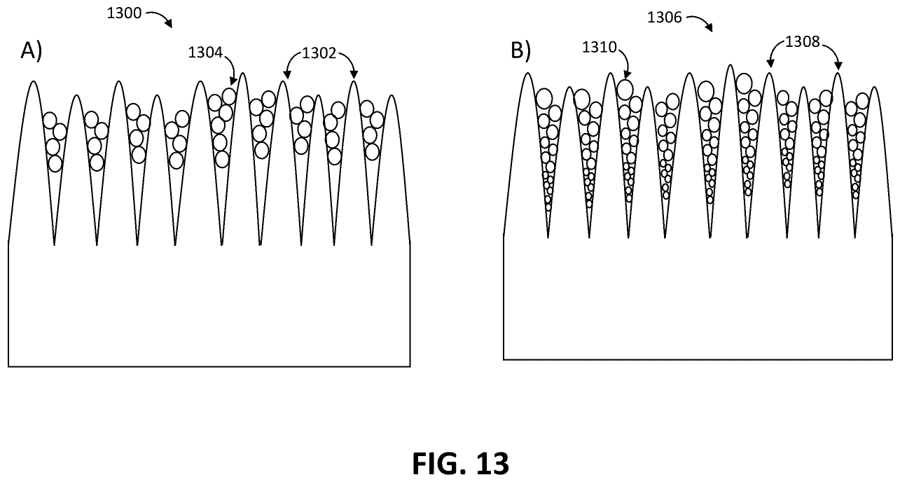

Part A of FIG. 13 shows a schematic, cross sectional view of an article 1300 having nanostructures 1302 interconnected with particles 1304 connected the top regions of the nanostructures 1302. Part B of FIG. 13 shows a schematic, cross sectional view of an article 1306 with nanostructures 1308 interconnected with heterogeneous particles 1310 filling the gap between nanostructures 1308.

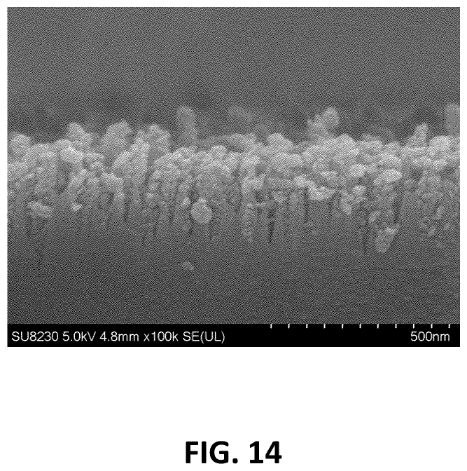

FIG. 14 shows a cross sectional, SEM image of an article having a substrate with interconnected nanostructures in its surface. In this example, the article includes nanoparticles interconnecting the distinct nanostructures composed of the substrate material.

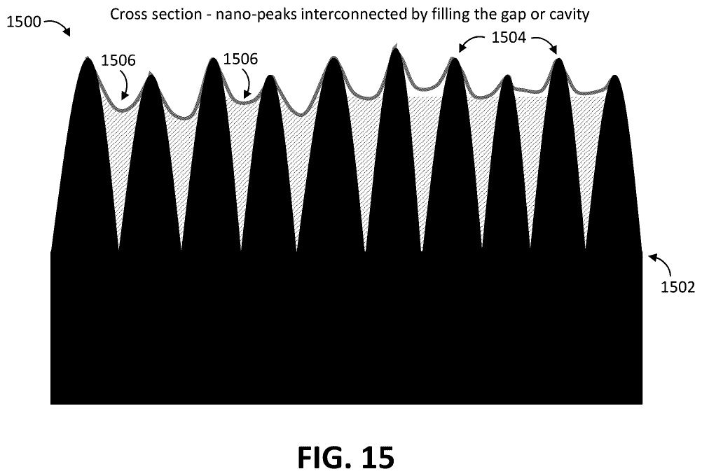

FIG. 15 shows a schematic, cross sectional view of an article 1500 having a substrate 1502 with interconnected nanostructures 1504 in its surface. In this example, the gaps between the nanostructures 1504 are filled with a different material 1506.

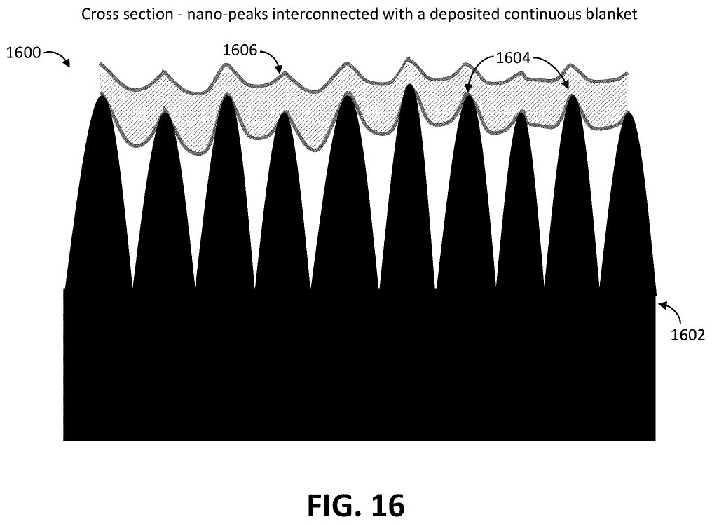

FIG. 16 shows a schematic, cross sectional view of an article 1600 including a substrate 1602 with interconnected nanostructures 1604 in its surface. In this example, the article 1600 includes a continuous film 1606 or blanket of material connecting a plurality of the nanostructures 1604.

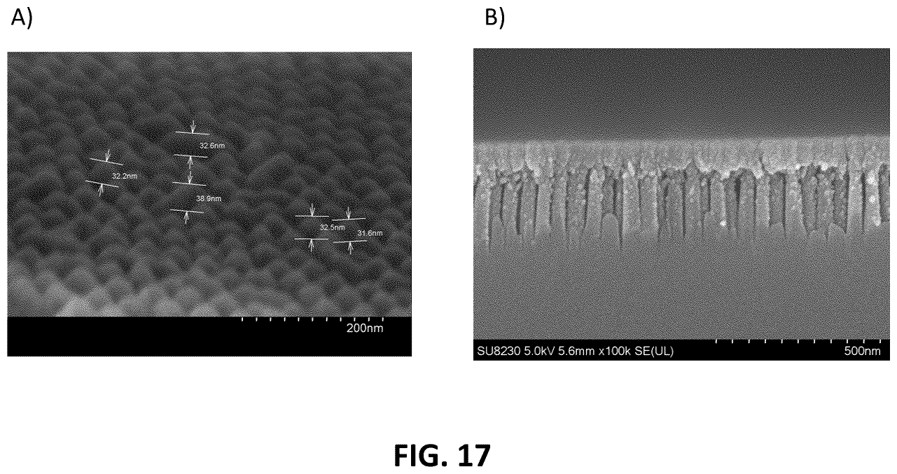

Parts A and B of FIG. 17 show SEM images of example articles having interconnected nanostructures in a substrate where the peaks of the nanostructure are interconnected by a continuous blanket of material. Part A of FIG. 17 shows surface relief in the blanket of material featuring elevated peaks and depressed valleys.

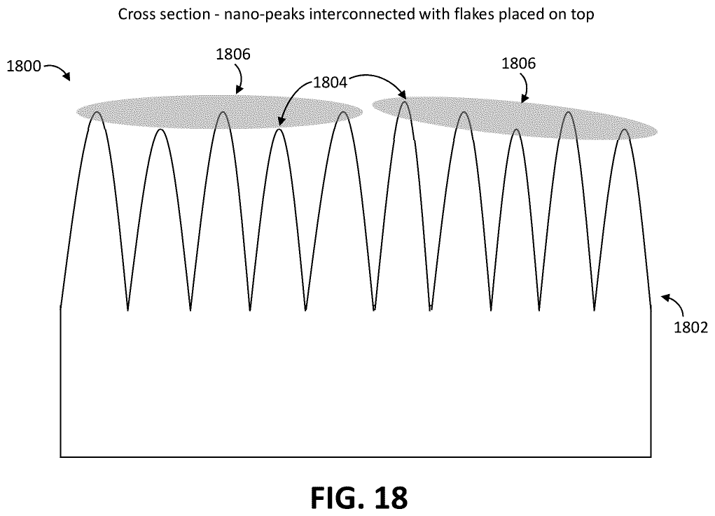

FIG. 18 shows a schematic, cross sectional view of an article 1800 including a substrate 1802 with interconnected nanostructures 1804 in its surface. In this example, subsets or pluralities of the nanostructures 1804 are interconnected by respective flakes 1806 of material at the nano or micro scale.

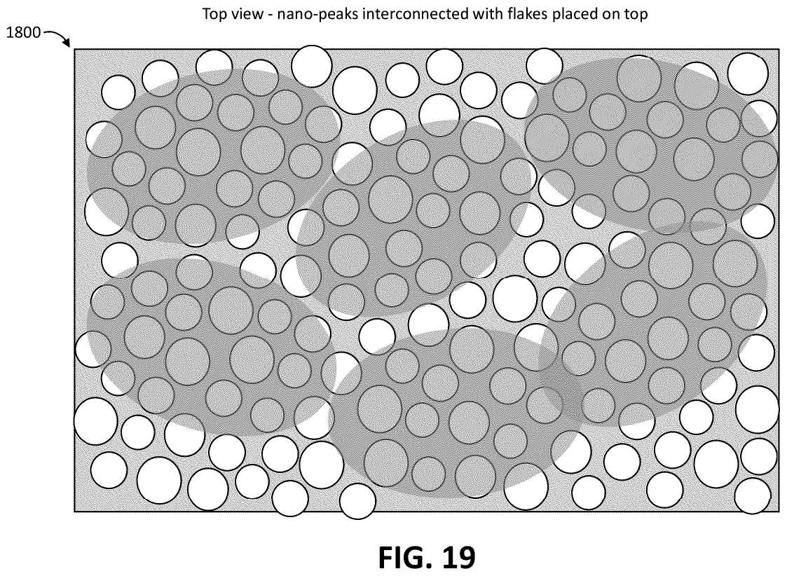

FIG. 19 shows a schematic, top view of the article 1800 of FIG. 18.

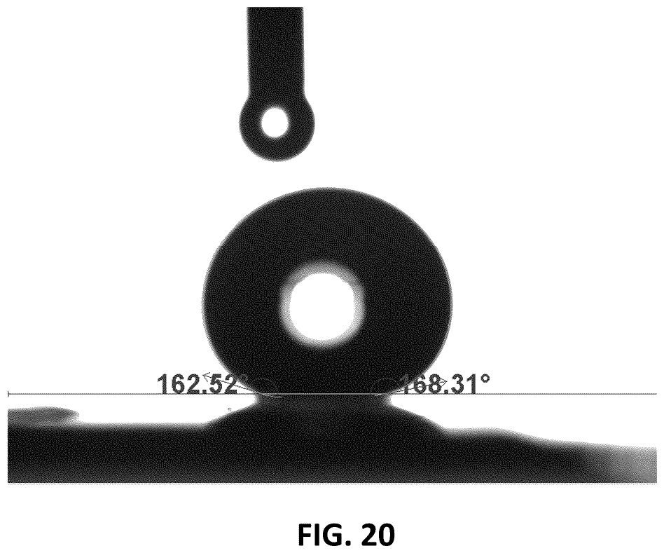

FIG. 20 shows the water contact angle on a superhydrophobic glass substrate featuring interconnected nanostructures and deposited hydrophobic fluorocarbon molecules on its surface. In this example, the contact angle is measured to be at a minimum of 162 degrees.

The disclosed articles and methods may provide a substrate with high transparency, low reflectivity, or both at all angles and broad wavelength while maintaining high mechanical and thermal stability. The disclosed articles and methods are applicable to various rigid or flexible substrates including plastics or polymers, glass, and semiconductors. Nanostructures are etched into the one or more of the surface of the substrate. The surface treatment may be applied to a homogenous substrate or a composite substrate, such as one coated with an additional material, where the treatment is then applied to the coated material. The term “substrate” is thus used herein to include substrates having a base substrate and one or more layers supported by the base substrate.

The nanostructures are sub-wavelength in lateral dimensions, where “sub-wavelength” refers to physical dimensions smaller than the wavelength of the incident light or electromagnetic waves. The wavelength of the incident light may be within and beyond the visible spectrum. The disclosed articles are useful in connection with a wide range of wavelengths.

The nanostructures are smaller than the wavelength of light such that at each depth of the nanostructures, there is an effective index of refraction that averages throughout the entire cross-sectional plane at that depth. For light hitting the surface at non-perpendicular angles or “wide-angles”, the cross-sectional plane for the effective index is perpendicular to the incidence angle. FIGS. 1 and 2 depict how sub-wavelength nanostructures create a continuous gradient in the effective index of refraction from the one medium through the nanostructures into the second medium. FIG. 1 shows incident light at normal incidence and FIG. 2 shows incident light at a wide angle, one that is not normal to the surface. Due to the sub-wavelength lateral dimensions of the nanostructures 102, the effective index gradient is averaged over a plurality of the nanostructures 102. An example of high transmission spectrum for nanotextured glass is shown in FIG. 3, showing broad-spectrum high transmittance and thus low reflectance at various angles of incidence.

The nanostructures are composed of, or formed in, the substrate, including polymers and plastics, glass, semi-conductors, ceramics, and other materials. Polymers and plastics may include but not limited to polycarbonate, polyethylene, polylactic acid, and polyethylene terephthalate among others. Glass may include borosilicate, soda lime, aluminosilicate, and fused silica, among others. Examples of other materials include silicon, gallium arsenide, perovskites, oxides, nitrides, and carbides.

The nanostructures are interconnected. The interconnected nature of the nanostructures provides mechanical durability to otherwise fragile nanostructures susceptible to mechanical breakage.

The lateral dimensions (e.g., peak to peak spacing) of the structures may be configured to control scattering and thus haze. Larger dimensions create haze whereas dimensions much smaller than the wavelength of relevant light will not scatter and do not have haze. The depths of the nanostructures are comparable or larger than the relevant wavelength of light such that there is an effective continuous change in the index of refraction through the relevant pathlength of the light. For light in the visible spectrum, for example, the depth may be a minimum of 100 nanometers. Other depths may be used in other cases.

The nanostructures are created by etching or nanoimprinting into the target substrate. Etching may include wet etching such as acid etching or dry etching such as reactive ion etching or plasma etching in vacuum or atmospheric pressure. Masks of various geometries may be used to etch nanostructures of various geometries.

In FIGS. 4 and 5, a lamellar or maze-like mask may be used with reactive ion etching to create the structures interconnected throughout the top and interior of the nanostructures to create interconnected structures much like mountain ranges. The top view of the nanostructures may look like elongated islands or an interconnected maze. Peaks and ridges are connected at various depths. Heights and depths of the structures may be varied (as shown in, e.g., FIG. 6). Tapered structures with low cross-sectional area at the top and high cross-sectional area at the bottom are created so to create a continuous gradient in the effective index of refraction as illustrated in, e.g., FIG. 1.

In FIG. 7, a masking pattern having circular or irregularly shaped islands may be used to etch interconnected nanostructures, where the structures are tapered and the heights and depths may differ so as to produce a continuous gradient in the effective index of refraction. A variety in the size and separation distance of the islands allows for varying start times in etching for different areas of the surface, where the edges of islands may be gradually removed by the etchant.

In FIGS. 8 to 12, an interconnected mask pattern with holes exposing the substrate may be used to etch interconnected nanostructures where the interior of the structures is connected at various depths. The nanostructures are tapered, and the height and depths of structures may be varied to produce the interconnected structures with a continuous gradient in the effective index of refraction.

A single etching step may be used to create the tapered interconnected nanostructures by using an etching process simultaneously performing isotropic etching (chemical reaction) and anisotropic etching (ion bombardment). Such etching recipes vary with the substrate and masking material. The etchant includes at least one component that is chemically reactive with the substrate. The etchant may also etch the substrate and mask at different rates, where the etchant is chemically more reactive with the substrate than the mask. The rate of anisotropic and isotropic etching for the mask differs from that of the substrate. As the areas of the substrate between masks begin to etch, isotropic etching contributes to a lateral etching direction. At the same time, anisotropic etching etches the substrate downward for areas not protected by the mask. Using this strategy, a conical or irregularly tapered geometry may be achieved, where there is a smaller cross-sectional area of the substrate at the top (peak) and larger cross-sectional area of the substrate at the bottom (base) of the nanostructures.

Alternatively, a mask with varying composition, thickness, density, or a combination of the three across the surface may be used for etching such tapered structures using primarily anisotropic etching. The lateral variations in composition, thickness, and or density of the mask creates a variety of etch rate for different areas, allowing for the exposure of the substrate at different times. This approach allows for the initiation of substrate etching at different times for different areas of the surface, thus allowing for the creation of nanostructured surface where peaks are interconnected at various depths, and where heights and depths of the nanostructures vary.

A mask pattern having patterned polymer domains may be used as a mask. However, the polymer pattern may be infiltrated with additional materials into target polymer groups on the surface of the substrate to enhance selectivity against the etchant compared to the substrate. The target polymer group may form various patterns such as a maze-like structure, islands, or holey pattern via self-assembly of polymer on the surface. The infiltration of the masking material can be a gas phase infiltration such as sequential infiltration synthesis, a vapor-based infiltration in a chamber, or a liquid-based infiltration in a solution. Masking materials may include various materials with differing etching selectivity than the substrate, and may include inorganic materials or compounds, including metal, metalloids, semiconductors, or their oxides or other compounds. For example, the inorganic materials or compounds may include aluminum oxide, titanium dioxide, zinc oxide, silicon dioxide, hafnium dioxide, zirconium dioxide, and tungsten, and/or others.

Masks with a lateral variety in thickness in a nanodomain may be created by varying the thickness of the target polymer. For instance, this may be achieved via the removal of one domain of polymer prior to infiltration, such as the remaining domain takes on a dome-shape or tapered edge geometry.

Masks with lateral variety in density within a nanodomain may be created by partial infiltration of the target polymer domain such that the infiltration is not saturated. As such, the infiltration density near the surface of the polymer is higher than the areas far from the surface.

Masks with a lateral variety in composition may be created by using multiple domains of polymer such as the use of a AB block copolymer mixed with a C homopolymer or an ABC block copolymer, for example, where different materials are infiltrated into distinct polymer domains.

The polymer pattern may be formed by the self-assembly of block copolymers where one or more domain of the block copolymer is comprised of the target polymer with specificity to the infiltration agent. The block copolymer self-assembly can form various domain patterns depending on the polymer composition and the self-assembly conditions such as temperature, pressure, and the chemical composition of the environment.

Distance between the peaks of nanostructures may be controlled by altering the polymer. Polymer chain lengths may be increased to increase the distance between the polymer domains prior to etching, resulting in increased distance between peaks in the nanostructures on the etched surface. For example, for a 30:70 mole ratio polystyrene-block-polymethylmethacrylate (PS-b-PMMA) polymer forming columns of PS within a web of PMMA, the distance between polystyrene columns may be increased by increasing the chain length of the polymer or decreased by decreasing the chain length of the polymer, while preserving the mole ratio. Similar, for a 70:30 ratio PMMA-b-PS polymer forming columns of PMMA within a web of PS. Similarly, instead of extending the length of a particular domain in the block copolymer, homopolymer composed of one of the domains or one chemically similar to one domain may be added to mixture, with composition ratio affecting the lateral dimensions of the pattern. Polymer mixtures composed of, or otherwise including, three polymer domains may be used, either in the form of a triblock polymer including three domains or via mixture of a block copolymer having two domains with a homopolymer with chemical characteristics similar to one of the block copolymer domains or between that of the two domains. Examples of polymer domains used for such self-assembly may include: PS, PMMA, polyvinylpyridine such as P2VP and P4VP, polybutadiene, and polyethyleneoxide (PEO), among others.

After nanostructures are etched into the substrate, additional elements, molecules, or particles may be deposited. This deposition may create additional interconnection between the structures to strengthen the mechanical durability or the deposition can alter the surface energy of the surface so as to create various properties, including, for instance, superhydrophobicity, superhydrophilicity and oleophobocity.

Nanoparticles or films smaller than the distance between nanostructures may be deposited between the nanostructures (see, e.g., FIGS. 13, 14, and 15). Such particles may connect one nanostructure to another. A matrix with effective index of refraction between that of the two media may also be deposited between or on top of the structures such that there is a continuous gradient in the effective index of refraction from the top of the nanostructures to the bottom. Such materials may be composed of, or otherwise include, solid materials such as MgF₂, silicon oxide or polymer or a porous matrix where the sizes of pores are smaller than the relevant wavelength of light.

As shown in FIGS. 16 to 19, particles or films may be deposited on top of the nanostructures where the particles may connect a plurality of nanostructures. Such particles may take on various geometries such as planar flat structures like a film (FIGS. 16 and 17), a plate like structure connecting a limited number of nanostructures (FIGS. 18 and 19), sphere-like structures (FIGS. 13 and 14). The structures may be irregularly shaped structures or have other geometries.

Such deposition may occur via liquid deposition techniques such as drop casting, sol-gel, Langmuir-Blodgett, or other methods. Particles may also be deposited in vacuum-based processes such as sputtering, physical vapor deposition, chemical vapor deposition, passivation, atomic layer deposition and other similar approaches. The composition of the particles or film may include polymers, metal, or metal oxide or other materials, examples of which include polystyrene, titanium dioxide, silicon dioxide, and fluorinated compounds.

Particles or films may be chemically bonded to the structures via functional groups on the surface of the particle or the nanostructures. Particles may also be bonded to the structure via heat treatment. Particles may also be held in place simply via other forces such as van der Waals interactions.

Particles or films may be composed of a low surface energy material such to grant the surface with properties such as a superhydrophobic functionality. An example includes fluorinated compounds such as polytetrafluoroethylene. Another example includes titanium dioxide in the form of nanoparticles or composites. Particles or films may be composed of a high surface energy material such to grant the surface with properties such as superhydrophilicity. Such surface properties may grant a self-cleaning effect for the surface.

A number of examples of the disclosed articles and methods are now described.

Example 1: An anti-reflective glass substrate with nanostructures in the surface where the nanostructures interconnected at various depths fabricated with a gradient in the effective index of refraction from above the top of the nanostructures to below the bottom of the nanostructures (FIG. 9). PS-b-P2VP block copolymer deposited on the surface of the glass may be induced to form nanopatterns via tetrahydrofuran vapor annealing, forming domains of approximately 25 nm diameter PS islands in an interconnected P2VP matrix on the surface of the substrate. Anionic metal salts such as tetrachloroaurate ions may be selectively infiltrated and electrostatically bonded into the positively charged P2VP block via liquid emission. The infiltrated metal takes on the pattern of the P2VP domain on the surface of the glass substrate, forming a network of nanopatterned hard mask. Plasma etching based on a fluorine-based gas mixture is used to etch the glass surface with hard mask. An 8-to-1 ratio of CHF₃-oxygen gas mixture is used at 10 mTorr pressure with 1000W and 100W ICP and RIE power to induce a mixture of isotropic etching and anisotropic etching mechanisms. Gas mixtures composed of CF₄, C₄F₈, and SF₆ may also be used. The lateral dimension of the mask may decrease over the etch time, allowing for the newly exposed glass surface to begin etching at different times of the process. This combination of isotropic and anisotropic etching creates nanostructures with distinct peaks, featuring varied heights and depths, and where nanostructures are interconnected at various depths such there is a hyperbolic paraboloid surface geometry at such interconnections.

Example 2: Nanostructures may be interconnected with additional deposition of materials such as MgF₂ nanoparticles (FIG. 14 show the one with particles connecting structures) so as to provide additional resistance against mechanical abrasion. Similar to above, PS-b-PMMA may be used to create islands of PMMA in a network of PS on the surface of a glass surface. Alumina or gallium-based masks may be infiltrated into the PMMA domains using trimethyl forms of the metal along with alternating vapor-based exposure with water vapors for sequential infiltration synthesis, forming metal-containing or organometallic nano-island hard masks. Reactive ion etching with inductively coupled plasma is used for etching, using simultaneous isotropic and anisotropic mechanisms. A mixture of Halogen and oxygen gases are used for the etching, for instance a 45 sccm CF₄—5 sccm oxygen mixture at 25 mTorr pressure. 1000W and 100W ICP and RIE power is used. FIG. 14 shows conical structures of varied heights and depths are etched into the glass substrate. MgF₂ particles with diameters smaller than 40 nm are deposited via sputtering at a rate of 1 nm per second. Flash heating may be used to further fuse the particles and nanostructures. The result is an interconnected nanostructured surface featuring tapered or conical glass structures interconnected by MgF₂ nanoparticles or nanostructures that feature a continuous gradient in the cross-sectional area from above the top of the nanostructure to below the bottom of the nanostructures.

Example 3: Polystyrene nanoparticles are assembled in a two-dimensional array on the surface of a glass substrate. Spin coated on the surface, 50 nm diameter nanoparticles form a monolayer across the surface of the substrate. Sputtering is then used to deposit gold on the whole surface, where metal is deposited on the substrate in-between the nanoparticles. Nanoparticles are then removed using toluene and the deposited gold on the substrate forms a hard mask. With similar plasma etching method as described in Example 1, a fluorine-based gas mixture with oxygen is used to etch the glass surface with the gold acting as a hard mask. A 10-to-1 ratio of SF₆-oxygen gas mixture is used at 20 mTorr pressure with 1000W and 150W ICP and RIE power to create at the surface of the glass substrate interconnected peaks showing hyperbolic paraboloid surfaces in-between each peak. After formation of this nanotexturing, nanoflakes of graphene oxide of approximately 100 nanometer width and less than 30 nanometer thickness are deposited using spin coating. The result is a glass substrate with nanotextures on the surface with a plurality of nanostructure connected by nanoflakes (FIGS. 18 and 19).

Example 4: FIGS. 4, 5 and 6 show lamellar or maze-like geometry in top-view by scanning electron microscopy. Self-assembly of block copolymers with a world-like lamellar interconnected mesostructured nanopattern is assembled on the surface of the glass via control of chain length and domain mole ratio. One domain of the polymer pattern is infiltrated with metal, forming a lamellar hard mask nanopattern. Reactive ion etching is used to etch the substrate. Instead of conical nanostructures, substrate formations resulting of plasma etching become sharp-tips interconnected in the middle by hyperbolic surfaces, which may be explained as interconnected mountain-like ridges. From the top view, these nanostructures resemble a maze-like or a lamellar structure in which alternating materials are provided layer by layer (FIG. 6). After the etching, from the side view or cross section, the structures look like single peaks, double peaks or a wall depending on the angle of intersection with the structure (FIG. 4). On a single feature of the maze-like mask, when the top view look like a curved line with variable thickness, the etching process removes thinner parts of the line faster and hence the structure underneath is exposed to the etchant faster than the other parts, hence starting the etch earlier. This varied exposure to the etchant creates a variable height and depth throughout the length of the single feature and creates double peaks and hyperbolic surfaces.

Example 5: For increasing haze of the surface, peak to peak distance of the nanostructures may be increased to about 100 nanometers and the etching depth to about 200 nm, so as to scatter light. Increasing the etching depth increases light scattering and hence haze in the shorter wavelength region in ultraviolet and visible light and improves the anti-reflective properties for near-infrared and infrared wavelength. Conversely, peak to peak distance of 40 nanometers provides a surface with no visible or detectable scattering in visible light.

Example 6: Nanostructured surfaces may enhance some surface properties of the same non-nanostructured materials. For example, a relative flat or featureless hydrophobic surface may become superhydrophobic via the combination of hydrophobic surface and nanotexturing. It is also possible to change the surface property of a nanotextured material by applying a specific coating after its nanotexturing. For example, on a nanostructured substrate like glass, coating a hydrophobic layer makes it superhydrophobic. After the texturing of a glass surface, hydrophobic fluorocarbon polymers are deposited via vacuum deposition of fluorocarbons using C₄F₈ passivation gas. The deposition took place in the chamber of a Deep Reactive Ion Etcher (DRIE) by using a continuous flow of 65 sccm of C₄F₈, under a 12 mTorr vacuum, at a power of 10 W and 450 W for the RIE and ICP power, respectively. After deposition, the water contact angle is measured to be 162 degrees (FIG. 20), resulting in a nanotextured anti-reflection glass surface with superhydrophobic self-cleaning properties.

Example 7: Superhydrophobic surfaces may be made via deposition of elements or molecules after the etching of the nanostructured surface. Prior to the deposition on glass, the glass surface may be activated for hydroxyl groups using oxygen plasma, UV-ozone treatment, or other cleaning procedures, an optional step that may be used to ensure the highest quality of deposition. After the optional cleaning step, 0.1 mM octadecyltrichlorosilane was dissolved in hexane. The solution was then drop-casted on the surface or the surface submerged into the solution for 4 hours followed by heating at 120 C for 1 hour. This procedure forms an alkyl-functionalized nanostructured surface, featuring a superhydrophobic surface property where water contact angle may exceed 150 degrees.

Example 8: Copolymers of two or more domains may be used for microphase separation in creating patterned surfaces of a substrate such as glass. An example of a two-domain system is PS-b-PMMA, with a mole ratio of 30 to 70, for example, annealed at approximately 200 degrees Celsius to form columns of PS within a matrix of PMMA. An example of a three-domain block copolymer system is polystyrene-block-polybutadiene-block-polytetbutylmetharylate, also capable of forming column-like structures with three domains when exposed to THF vapor at room temperature. The formation of vertical domains allows for selectivity infiltration of metal or metal oxide via sequential infiltration synthesis, such as using TMA to form alumina. Multiple domains allow for varied degree of infiltration and thus varying density or composition of the metal or metal oxide composition formation. A pattern of such a mask with varying selectivity against the substrates allows for varying levels of protection against etching for different parts of the surface. Such mask allows for a variety in start times of the etching. When etched under a one-step reactive ion etching, the patterned mask on the surface allows for etching of various depths on different parts of the substrate, allows for the creation of nanostructures with a hyperboloid surface featuring distinct peaks and valleys of various height and depths, where the peaks are connected to each other at various depths (FIG. 7C).

Example 9: Hard masks of varying density at different lateral locations allow for varied rates of etching of the mask and thus creating different start times for exposure and etching of the substrate surface. Using a PS-b-PMMA block copolymer film, alumina is infiltrated via sequential infiltration synthesis. 3 cycles at 3 minutes infiltration periods for each precursor are used such that the infiltration is not saturated within the polymer domains. As such, infiltrated polymer domains near the surface have higher metal density compared to the interiors of the target domains. Primarily directional physical etching may then be used for the etching process. The variation in density of the hard mask allows for different etch rate of the mask. For a mask shaped like islands, the sides of the islands are gradually etched away in a physical etching, thus gradually exposing more of the substrate surface. This creates a tapered nanostructured surface. For areas where the distance between the islands is small, etching of that area may be later than areas with large distance between islands. This allows for a variety in depth of etching where the former case has shallow etch depths. This strategy of non-saturation infiltration creating a variable density in the hard mask allows for an anisotropic etching approach towards creating anti-reflection nanostructures with a continuously changing cross-sectional area from top to bottom of the structures and where structures are interconnected at various depths, and where the structures have a variety of heights and depths.

Example 10: After forming etched nanostructures in the surface of a substrate, porous materials may be added to between the structures for mechanical stability, where the effective refractive index of the added material is between the substrate and the other medium such as air. For example, interconnection between nanostructures created on the glass may be created using PS-b-PMMA block copolymers. Optionally, additional PMMA homopolymer may be added to the polymer solution for increased porosity. The PS-b-PMMA block copolymer is deposited on the surface and fills the gap between the peaks of the nanostructures. PMMA is subsequently washed off by acetic acid solvent which creates a porous scaffold between the nano-peaks, improving the mechanical stability. Before applying acetic acid, the PMMA can be degraded by exposure to UV light to facilitate removal. The porous structure has a refractive index between air and glass which can be controlled by the porosity of the polymer. The porosity of the polymer is controlled by the ratio of PS-b-PMMA in the coated layer. The higher ratio of PMMA polymer chain results in higher porosity. An optional step is the use of short oxygen plasma treatment to further create additional porosity or remove excess polymer above the peaks of the glass nanostructures. The end result is a surface with a continuous in the effective index of refraction from air into glass, where a porous polymer connects a plurality of glass nanostructures, delivery enhanced mechanical durability and omni-directional anti-reflection property.

Example 11: FIG. 17 shows the interconnected nanostructures fabricated by adding a blanket of MgF₂ on top of the nanostructures. The nanostructures are etched into fused silica substrate using and infiltrated hard-mask and the thin-film MgF₂ is deposited on the top using sputtering method by controlling the deposition speed and time. The MgF₂ thin-film blanket may have a porous structure and the peaks of the fused silica nanostructures creates bumps or physical features on the thin-film blanket. The uneven surface geometry creates a gradual transition in the effective index of refraction from the first medium such as air into the top of the MgF₂-glass material. The refractive index of MgF₂, is less than 1.2 especially when it is porous, and is between the refractive index of air, at 1, and fused silica glass at approximately 1.5. From the top of the nanostructures to the bottom, the cross-sectional area of glass, the high index medium, increases, whereas the cross-sectional area of air and MgF₂, the low effective index media, decrease. This creates a continuously changing effective index of refraction without any abrupt transition from the top of surface towards the interior of the substrate. This thus creates an anti-reflection surface with a blanket of material interconnecting nanostructures composed of the native substrate material.

The etchant may vary in other cases. For instance, with substrates such as soda lime glass, the etchant may include a mixture of a fluorinated gas, an oxidant, and a heavy noble gas, such as argon.

Described herein are articles with interconnected anti-reflective nanostructures formed in one or more surfaces of a substrate. The articles and/or methods described herein may alternatively or additionally include or involve any combination of one or more of the following aspects or features. The substrate includes one or more of a polymer, glass, sapphire, ceramic, or semi-conductor materials and have a top surface and a bottom surface. The nanostructures are interconnected in a hyperbolic paraboloid geometric surface such that the connections occur at a variety of depths. The nanostructures are composed of, or otherwise include, the material of the substrate. The nanostructures have defined peaks throughout the surface with peak to peak distances smaller than 100 nm and the distance or height of the tallest peak to the lowest valley is greater than 100 nm. The cross-sectional area of the structures is near zero at the top of the structures and continuously increases with depth until it reaches 100% at the bottom of the structures. One or more optical properties of the structures includes a continuous gradient in the effective index of refraction from the exterior of the surface on top of the nanostructures to the interior of the substrate below the bottom of the nanostructures. The effective hardness of the nanostructured surface is above 2 mohs. The anti-reflective property maintains less than 1% specular reflection at normal incidence and less than 20% specular reflection for incident light at 70 degrees from normal, for wavelengths from 450 to 1100 nm. The structures are formed from chemical etching, nanoimprinting, or reactive ion etching. The top view of the nanostructures includes separate islands or a continuous network of interconnected shapes. The two-dimensional shapes include one or a combination of regular geometries like circular or parabolic shapes or irregular shapes. Additional molecules or elements may be deposited on to the surface of the nanostructures to grant additional surface effects such as superhydrophobicity in the case of a low energy surface or hydrophobic material and superhydrophilicity in the case of a high energy surface material.

Described herein are articles with interconnected anti-reflective nanostructures formed in one or more surfaces of a substrate. The articles and/or methods described herein may alternatively or additionally include or involve any combination of one or more of the following aspects or features. The substrate includes one or more of a polymer, glass, sapphire, ceramic, or semi-conductor materials and has a top surface and a bottom surface. The cross-sectional area of the material of the nanostructures continuously varies from the top of the surface to the bottom of the nanostructures. The nanostructures have distinct peaks and are interconnected by a plurality of particles at various depths of the nanostructures, or by a porous material filling the gaps between nanostructures, or by particles on top of the nanostructures connecting a plurality of peaks, or by a thin film blanket-like structure connecting a plurality of peaks, or a combination of the four. The particles on top of the nanostructures may be planar, flake-like or irregularly shaped in geometry connecting a plurality of nanostructures with thickness ranging from atomic thickness to 100 nanometers. The thin film blanket has a thickness less than 100 nm and may have peaks and valleys at the surface of the thin film. The particles, porous materials, and thin film may include two-dimensional materials including graphene and graphene oxide, metal, metal oxide, metal compounds, polymer, semi-conductor, semiconductor compounds or a combination of multiple materials. One or more optical properties of the structures includes a continuous gradient in the effective index of refraction from the exterior of the surface on top of the nanostructures to the interior of the substrate below the bottom of the nanostructures. The effective hardness of the nanostructured surface is above 2 mohs. The anti-reflective property maintains, for wavelengths from 450 to 1100 nm, a less than 1% specular reflection for normal incidence and less than 20% specular reflection for incident light at 70 degrees from normal. The nanostructures are formed from chemical etching, nanoimprinting, or reactive ion etching. The top view of the nanostructures includes separate islands or a continuous network of interconnected shapes. The two-dimensional shapes may include one or a combination of regular geometries like circular or parabolic shapes or irregular shapes. Additional molecules or elements may be deposited on to the surface of the nanostructures to grant additional surface effects such as superhydrophobicity in the case of a low energy surface or hydrophobic material and superhydrophilicity in the case of a high energy surface material.

Described herein are methods of fabricating an anti-reflective article having anti-reflective nanostructures in a substrate includes forming a layer of polymer on the substrate, in which the polymer layer includes one or more polymers including at least one block copolymer, in which the polymer layer includes a pattern, in which the patterned polymer layer includes at least a first polymer domain and a second polymer domain, applying one or more precursors to the patterned polymer layer on the substrate to form a patterned mask of inorganic materials or compounds, including metals, metalloids, semiconductors, or their compounds on the substrate, in which the precursor does not infiltrate into at least one polymer domain, in which the precursor infiltrates into at least one polymer domain and forms inorganic material within the polymer domain, in which the infiltrated material has a lateral variety in density, thickness, or composition within 500 nanometer lateral dimension so as to create a varied etch rate or selectivity against the etchant, etching the substrate, in which the polymer domain without the infiltrated inorganic material is first removed by the etchant, allowing for etching of the substrate in those local areas, in which various parts of the mask laterally diminish in size during the etching or lifts off at various times, exposing masked areas to the etchant at different times, resulting in various etch depth throughout the masked domain at the end of the etching process, in which the etching is performed under etch times sufficiently long for inorganic material mask to lift off or erode, so as to create a nanostructured surface of the substrate material where there is a continuous gradient in the cross-sectional area from the top of the nanostructures to the base of the nanostructures and where the peaks of the nanostructures are interconnected at various depths such to form a hyperboloid or saddle-like surface at the interconnection points.

The methods described herein may alternatively or additionally include or involve any combination of one or more of the following aspects or features. One or more precursor infiltrates more than one polymer domain where the precursor generates an inorganic material in the polymer domains with different density, thickness, or composition such to create a variety of resistance or selectivity against the etchant. The inorganic materials or compounds includes a metal, metalloids, semiconductors or their compounds including aluminum oxide, titanium dioxide, zinc oxide, silicon dioxide, hafnium dioxide, zirconium dioxide, and tungsten, or others. More than one precursor is used for infiltration where the precursors selectively infiltrate different polymer domains. The precursor is in the form of gas, or liquid or plasma. One or more domains resemble dots, or a maze or a spider network, or parallel lines, or beehives, or spirals. One or more of the domains create an interconnected network. Additional layer or particles or nano flakes or nano plates are deposited on the etched surface such to create addition interconnection between peaks of the nanostructures. A heat-treatment or a chemical treatment stabilizes the structures or improve the adhesion of deposited material. The method includes an additional surface treatment or deposition of elements or molecules by gas, or liquid or plasma create a hydrophobic, or hydrophilic or oleophobic properties. The top view of the mask geometry and the nanostructures includes separate islands or a continuous network of interconnected shapes, wherein the two-dimensional shapes may include one or a combination of regular geometries like circular or parabolic shapes or irregular shapes.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An anti-reflective article comprising:
a substrate comprising a surface and a bulk; and
an arrangement of anti-reflective nanostructures along the surface of the substrate, each anti-reflective nanostructure of the arrangement of anti-reflective nanostructures being supported by the bulk of the substrate, each anti-reflective nanostructure of the arrangement of anti-reflective nanostructure tapering from the bulk of the substrate to define a respective peak;
wherein at least some of the anti-reflective nanostructures of the arrangement of anti-reflective nanostructures are linked with an adjacent anti-reflective nanostructure of the arrangement of anti-reflective nanostructures via a respective interconnection, the respective interconnections being in addition to the bulk of the substrate supporting the anti-reflective nanostructures, and
wherein the respective interconnections are disposed at or above a midpoint between the peaks of the anti-reflective nanostructures and the bulk of the substrate.

2. The anti-reflective article of claim 1, wherein the substrate comprises the respective interconnections.

3. The anti-reflective article of claim 1, wherein the interconnections are provided by a portion of the substrate between the adjacent anti-reflective nanostructures of the arrangement of anti-reflective nanostructures.

4. The anti-reflective article of claim 3, wherein the portion of the substrate defines a saddle-shaped section of the surface.

5. The anti-reflective article of claim 1, further comprising a distribution of nanoparticles disposed across the surface of the substrate such that each interconnection is provided by a respective subset of the distribution of nanoparticles.

6. The anti-reflective article of claim 5, wherein the nanoparticles in each subset closest to the peak are larger than the nanoparticles in each subset closest to the bulk.

7. The anti-reflective article of claim 1, further comprising a distribution of flakes across the substrate, wherein each flake of the distribution of flakes is in contact with the peaks of linked anti-reflective nanostructures of the arrangement of anti-reflective nanostructures such that each flake of the distribution of flakes provides one or more of the interconnections.

8. The anti-reflective article of claim 1, further comprising a filling across the substrate disposed in cavities defined by the arrangement of anti-reflective nanostructures such that each interconnection is provided by a respective portion of the filling.

9. The anti-reflective article of claim 1, further comprising a continuous film extending across the arrangement of anti-reflective nanostructures such that the continuous film provides the interconnections between the peaks of the anti-reflective nanostructures.

10. The anti-reflective article of claim 1, wherein the arrangement anti-reflective nanostructures is configured such that the peaks of each pair of adjacent anti-reflective nanostructures in the arrangement of anti-reflective nanostructures are spaced apart by a distance smaller than a wavelength of light incident upon the anti-reflective article.

11. The anti-reflective article of claim 1, wherein:
the arrangement of anti-reflective nanostructures establishes an effective index of refraction for light incident upon the anti-reflective article; and
each anti-reflective nanostructure of the arrangement of anti-reflective nanostructures is configured such that the effective index of refraction exhibits a continuous gradient from the respective peak of the anti-reflective nanostructure to a base of the anti-reflective nanostructure.

12. The anti-reflective article of claim 1, wherein:
the substrate comprises a base substrate and a layer supported by the base substrate; and
the layer comprises the arrangement of anti-reflective nanostructures.

13. The anti-reflective article of claim 1, wherein the surface of the substrate is shaped to define the arrangement of anti-reflective nanostructures.

14. An anti-reflection article comprising:
a substrate having a surface and a bulk; and
an arrangement of anti-reflective nanostructures along the surface of the substrate, each anti-reflective nanostructure of the arrangement of anti-reflective nanostructure being supported by the bulk of the substrate, each anti-reflective nanostructure of the arrangement of anti-reflective nanostructure tapering from the bulk of the substrate to define a respective peak;
wherein a height at which adjacent anti-reflective nanostructures of the arrangement of anti-reflective nanostructures are linked by an interconnection varies across the substrate, and
wherein at least some of the interconnections are disposed at a position equidistant between the peaks of the anti-reflective nanostructures and the bulk of the substrate.

15. The anti-reflection article of claim 14, wherein each pair of adjacent anti-reflective nanostructures of the arrangement of anti-reflective nanostructures is interconnected by a respective portion of the substrate.

16. The anti-reflection article of claim 14, wherein the adjacent anti-reflective nanostructures of the arrangement of anti-reflective nanostructures define a saddle-shaped surface.

17. The anti-reflection article of claim 14, further comprising a plurality of nanoparticles distributed across the arrangement of anti-reflective nanostructures such that each pair of adjacent anti-reflective nanostructures of the arrangement of anti-reflective nanostructures is interconnected by a respective subset of the plurality of nanoparticles.

18. The anti-reflective article of claim 17, wherein the number of the nanoparticles in each subset varies such that the depth at which adjacent anti-reflective nanostructures of the arrangement of anti-reflective nanostructures are interconnected varies.

19. The anti-reflective article of claim 17, wherein positioning of the nanoparticles in each subset varies such that the depth at which adjacent anti-reflective nanostructures of the arrangement of anti-reflective nanostructures are interconnected varies.

20. The anti-reflective article of claim 17, each subset comprises nanoparticles of varying size.

21. An anti-reflective article comprising:
a substrate comprising a surface and a bulk; and
an arrangement of anti-reflective nanostructures along the surface of the substrate, each anti-reflective nanostructure of the arrangement of anti-reflective nanostructures being supported by the bulk of the substrate, each anti-reflective nanostructure of the arrangement of anti-reflective nanostructure tapering from the bulk of the substrate to define a respective peak;
wherein some of the anti-reflective nanostructures of the arrangement of anti-reflective nanostructures are linked with an adjacent anti-reflective nanostructure of the arrangement of anti-reflective nanostructures via a portion of the substrate in addition to the bulk of the substrate, the portion defining a saddle-shaped section of the surface.

22. An anti-reflective article comprising:
a substrate having a surface and a bulk, the surface being shaped to define an arrangement of anti-reflective nanostructures, each anti-reflective nanostructure of the arrangement of anti-reflective nanostructure tapering from the bulk of the substrate to define a respective peak; and
a distribution of material across the surface of the substrate;
wherein a portion of the distribution of material is disposed between adjacent anti-reflective nanostructures of the arrangement of anti-reflective nanostructures such that the adjacent anti-reflective nanostructures of the arrangement of anti-reflective nanostructures are interconnected by the portion of the distribution of material.

23. The anti-reflective article of claim 22, wherein the distribution of material comprises a plurality of nanoparticles disposed in cavities defined by the arrangement of anti-reflective nanostructures.

24. The anti-reflective article of claim 22, wherein the distribution of material comprises a distribution of flakes across the substrate such that each flake of the distribution of flakes interconnects two or more of the peaks of the anti-reflective nanostructures.

25. The anti-reflective article of claim 21, wherein the material of the distribution comprises a filling across the substrate disposed in cavities defined by the arrangement of anti-reflective nanostructures.

26. The anti-reflective article of claim 21, wherein the material of the distribution comprises a continuous film extending across the arrangement of anti-reflective nanostructures such that the continuous film provides the interconnections between the peaks of the anti-reflective nanostructures.

27. A method of fabricating an anti-reflective article, the method comprising:
forming a mask on a substrate, the mask having a lamellar nanopattern; and
etching the substrate through openings in the mask defined by the lamellar nanopattern;
wherein etching the substrate comprises implementing an anisotropic etch such that an arrangement of tapered nanostructures are formed in accordance with the lamellar pattern.

28. A method of fabricating an anti-reflective article, the method comprising:
forming a mask on a substrate, the mask having a nanopattern of holes; and
etching the substrate through the holes in the mask defined by the nanopattern;
wherein etching the substrate comprises implementing an anisotropic etch such that an arrangement of tapered nanostructures is formed in accordance with the nanopattern of holes, and
wherein the nanopattern of holes is configured such that the arrangement of tapered nanostructures has saddle-shaped surfaces at interconnections between adjacent tapered nanostructures of the arrangement of tapered nanostructures.
